(19) United States
(12) Patent Application Publication
(10) Pub. No.: US 2026/0135381 A1
(43) Pub. Date: May 14, 2026

(54) SYSTEM AND METHOD FOR DETERMINING ONE OR MORE ABNORMALITIES IN A TRANSFORMER OF A POWER DISTRIBUTION SYSTEM

(71) Applicant: Aclara Technologies LLC, St. Louis, MO (US)

(72) Inventors: Lakshan Piyasinghe, Saint Charles, MO (US); Seyed Younes Seyedi, Ballwin, MO (US)

(21) Appl. No.: 19/384,608

(22) Filed: Nov. 10, 2025

Related U.S. Application Data
(60) Provisional application No. 63/718,835, filed on Nov. 11, 2024.

(51) Int. Cl. H02J 3/00; G01R 27/02; G01R 31/62; H02J 13/00

(52) U.S. Cl. CPC H02J 3/0012; G01R 27/02; G01R 31/62; H02J 13/12; H02J 13/333

(57) ABSTRACT

A method may include sensing, via a sensor, one or more electrical characteristics of the transformer. The method may further include receiving, via a controller, the one or more electrical characteristics of the transformers. The method may further include determining, via the controller, time series data of the one or more electrical characteristics of the transformer. The method may further include determining, based on the time series data, an estimated impedance of the transformer. The method may further include comparing, via the controller, the estimated impedance to an impedance model. The method may further include determining, via the controller, based on the comparison, an abnormality of the transformer. The method may further include outputting a signal indicative of the abnormality of the transformer.

### RELATED APPLICATIONS

This application claims priority to U.S. Provisional Patent Application No. 63/718,835, filed Nov. 11, 2024, the entire contents of both of which are incorporated herein by reference.

### FIELD

Embodiments relate to power distributions systems including one or more transformers.

### SUMMARY

Service transformers are widespread elements in power distribution systems that are required to deliver power to residential or commercial customers. Service transformers have a relatively large impedance (compared with service lines and feeders) which plays important role in power flow calculations and distribution system state estimation.

The transformer impedance may change over time. It is known that many utilities may have incorrect information about the rating/impedance of their transformers in their databases. Under such circumstances, the automation and control systems cannot reliably estimate/predict the actual system state/response which makes the entire system vulnerable to extreme events and stressed operating conditions.

Accurate estimation of transformer impedance using AMI data (i.e., voltage magnitude, active and reactive powers) is a challenging task. Traditionally, AMI data has been used to estimate the line impedances for distribution system state estimation and topology identification. Detection of abnormal transformer impedance has been studied in the literature however; the previous methods require extensive synchronized phasor measurements (including voltage phase angles) at different locations. In many practical scenarios, there is no sensor at the location of consumers which is capable of measuring synchro phasor data.

Thus, in some aspects, the techniques described herein relate to a method of determining one or more abnormalities in a transformer of a power distribution system, the method including: sensing, via a sensor, one or more electrical characteristics of the transformer; receiving, via a controller, the one or more electrical characteristics of the transformers; determining, via the controller, time series data of the one or more electrical characteristics of the transformer; determining, based on the time series data, an estimated impedance of the transformer; comparing, via the controller, the estimated impedance to an impedance model; determining, via the controller, based on the comparison, an abnormality of the transformer; and outputting a signal indicative of the abnormality of the transformer.

In some aspects, the techniques described herein relate to a method, wherein the one or more electrical characteristics include at least one selected from a group consisting of a voltage magnitude, an active power delivered by the transformer, and a reactive power delivered by the transformer.

In some aspects, the techniques described herein relate to a method, wherein the step of determining the estimated impedance includes: determining a total least square problem based on the one or more electrical characteristics.

In some aspects, the techniques described herein relate to a method, wherein the step of determining the estimated impedance includes: implementing a linear regression-based method based on the one or more electrical characteristics.

In some aspects, the techniques described herein relate to a method, wherein the signal initiates at least one selected from a group consisting of a shutdown procedure of the transformer, an inspection of the transformer, a diagnostic check of the transformer, and an alert to a user.

In some aspects, the techniques described herein relate to a method, wherein the signal is received by an external computing device.

In some aspects, the techniques described herein relate to a method, wherein the impedance model is based on previously sensed electrical characteristics of the transformer.

In some aspects, the techniques described herein relate to a method, further including: creating estimation of the transformer impedances using the previously sensed electrical characteristics of the transformer and a multi-stage regression model.

In some aspects, the techniques described herein relate to a power distribution system including: a transformer; an electrical meter connected to the transformer, the electrical meter configured to sense, via a sensor, one or more electrical characteristics of the transformers; and a controller having an electronic processor, the controller communicatively coupled to the electrical meter, the controller configured to: receive the one or more electrical characteristics of the transformers from the electrical meter; determine time series data of the one or more electrical characteristics of the transformer; determine an estimated impedance of the transformer; compare the estimated impedance to an impedance model; determine based on the comparison, an abnormality of the transformer; and output a signal indicative of the abnormality of the transformer.

In some aspects, the techniques described herein relate to a system, wherein the one or more electrical characteristics include at least one selected from a group consisting of a voltage magnitude, an active power delivered by the transformer, and a reactive power delivered by the transformer.

In some aspects, the techniques described herein relate to a system, wherein the step of determining the estimated impedance includes: determining a total least square problem based on the one or more electrical characteristics.

In some aspects, the techniques described herein relate to a system, wherein the controller determines the estimated impedance by: implementing a linear regression-based method based on the one or more electrical characteristics.

In some aspects, the techniques described herein relate to a system, wherein the signal initiates at least one selected from a group consisting of a shutdown procedure of the transformer, an inspection of the transformer, a diagnostic check of the transformer, and an alert to a user.

In some aspects, the techniques described herein relate to a system, wherein the signal is received by an external computing device.

In some aspects, the techniques described herein relate to a system, wherein the impedance model is based on previously sensed electrical characteristics of the transformer.

In some aspects, the techniques described herein relate to a system, further the controller is further configured to: create estimation of the transformer impedances using the previously sensed electrical characteristics of the transformer and a multi-stage regression model.

Other aspects of the application will become apparent by consideration of the detailed description and accompanying drawings.

### BRIEF DESCRIPTION OF THE DRAWINGS

FIG. 1 illustrates a power distribution system, according to some embodiments.

FIG. 2 is a block diagram of a meter of the power distribution system of FIG. 1, according to some embodiments.

FIG. 3 is a block diagram of a controller of the power distribution system of FIG. 1, according to some embodiments.

FIG. 4 illustrates a feeder segment of the power distribution system of FIG. 1, according to some embodiments.

FIG. 5 is a flowchart illustrating a method for determining one or more abnormalities in a transformer of the power distribution system of FIG. 1, according to some embodiments.

### DETAILED DESCRIPTION

Before any embodiments of the application are explained in detail, it is to be understood that the application is not limited in its application to the details of construction and the arrangement of components set forth in the following description or illustrated in the following drawings. The application is capable of other embodiments and of being practiced or of being carried out in various ways.

Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. As used within this document, the word “or” may mean inclusive or. As a non-limiting example, if examples in this document state that “item Z may comprise element A or B,” this may be interpreted to disclose an item Z comprising only element A, an item Z comprising only element B, as well as an item Z comprising elements A and B.

As used herein, “meter” may refer to a connected utility meter, an end point, an end device, an advanced metering infrastructure (“AMI”) meter from Aclara Technologies®, a meter communication add-on, or other metering device as required for a given application.

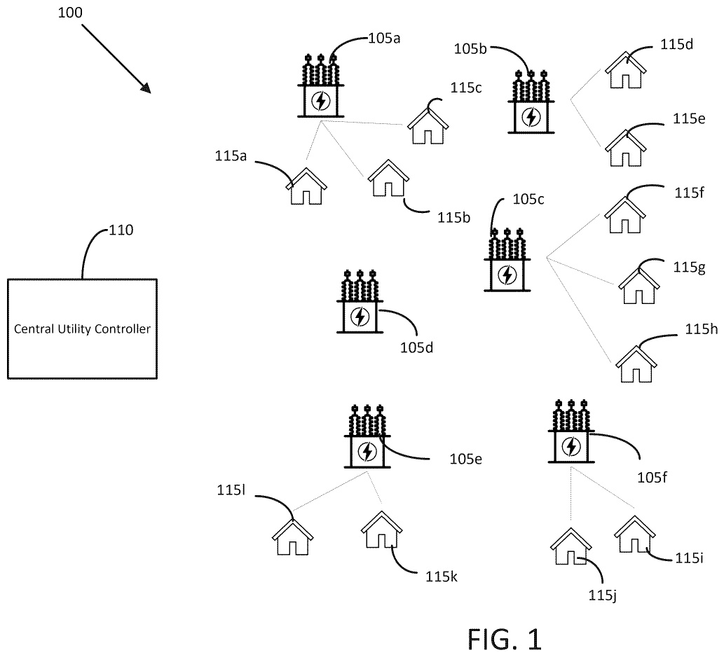

FIG. 1 illustrates a power distribution system 100 according to some embodiments. The power distribution system 100 includes one or more power transformers 105 (such as, but not limited to, one or more service transformers). The transformers 105 may be pad mounted transformers, pole mounted transformers, underground transformers, substations transformers, and/or other transformers as required for a given application. The transformers 105 are generally configured to step-down a utility power voltage level to a level that is suitable for distribution. The transformers 105 may be distributed across the system 100 to ensure that power is efficiently and economically distributed to customers.

The system 100 may further include a central utility controller 110. The central utility controller 110 may be in communication with one or more transformers 105 and/or other components within the system 100. The central utility controller 110, as will be described in more detail below, may be configured to sense, and determine, abnormalities of the utility system 100 (including, but not limited to, abnormalities of the one or more transformers 105). The system 100 may further include one or more smart meters 115 electrically and/or communicatively coupled to the one or more transformers 105.

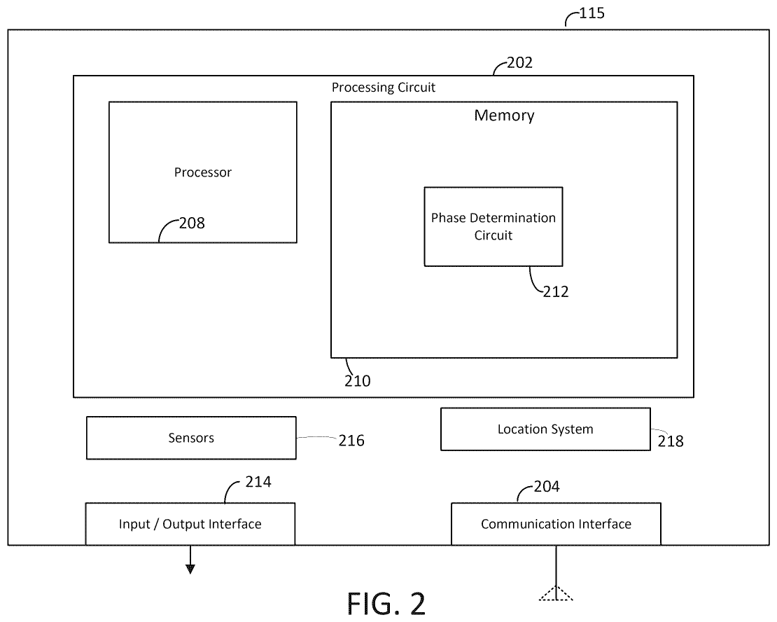

FIG. 2 is a block diagram of a meter 115, according to some embodiments. As shown in FIG. 2, the meter 115 includes a processing circuit 202, a communication interface 204, an input/output (I/O) interface 214, and one or more sensors 216. The processing circuit 202 includes an electronic processor 208 and a memory 210. The processing circuit 202 may be communicably connected to one or more of the communication interface 204 and the I/O interface 214. The electronic processor 208 may be implemented as a programmable microprocessor, an application specific integrated circuit (ASIC), one or more field programmable gate arrays (FPGA), a group of processing components, or with other suitable electronic processing components.

The memory 210 (for example, a non-transitory, computer-readable medium) includes one or more devices (for example, RAM, ROM, flash memory, hard disk storage, etc.) for storing data and/or computer code for completing or facilitating the various processes, layers, and modules described herein. The memory 210 may include database components, object code components, script components, or other types of code and information for supporting the various activities and information structure described in the present application. According to one example, the memory 210 is communicably connected to the electronic processor 208 via the processing circuit 202 and may include computer code for executing (for example, by the processing circuit 202 and/or the electronic processor 208) one or more processes described herein.

The communication interface 204 is configured to facilitate communication between the meter 115 and one or more external devices or systems, the central utility controller 110, and/or one or more other meters. The communication interface 204 may be, or include, wireless communication interfaces (for example, antennas, transmitters, receivers, transceivers, etc.) for conducting data communications between the meter 115 and one or more external devices, such as another meter or the central utility controller 110. In some embodiments, the communication interface 204 utilizes a proprietary protocol for communicating with other meters 115 or the central utility controller 110. For example, the proprietary protocol may be an RF-based protocol configured to provide efficient and effective communication between the meters 115 and other devices. In other embodiments, other wireless communication protocols may also be used, such as cellular (3G, 4G, 5G, LTE, CDMA, etc.), Wi-Fi, LoRa, LoRaWAN, Z-wave, Thread, and/or any other applicable wireless communication protocol.

The I/O interface 214 may be configured to interface directly with one or more devices, such as a power supply, a power monitor, etc. In one embodiment, the I/O interface 214 may utilize general purpose I/O (GPIO) ports, analog inputs, digital inputs, etc. The sensors 216 may include one or more sensors configured to monitor one or more aspects of a distribution line coupled to the meter 115. For example, the sensors 216 may include voltage sensors, current sensors, temperature sensors, and other sensors as required for a given application. In some embodiments, the sensors 216 may be connected to the distribution line using the I/O interface 214.

The meter 115 may further include a location system 218. The location system 218 may provide location data of the meter 115. In some examples, the location system 218 may utilize geolocation satellite data (e.g., GPS, GLONASS, etc.) to determine a location of the meter 115. However, other location determination technologies (e.g., cellular triangulation, Wi-Fi location, or other location service required for a given application) may also be used by the location system 218.

As described above, the memory 210 may be configured to store various processes, layers, and modules, which may be executed by the electronic processor 208 and/or the processing circuit 202. In one embodiment, the memory 210 includes a phase determination circuit 212. The phase determination circuit 212 is configured to determine, in concert with the electronic processor 208 and the sensors 216, phase information of the electrical utility monitored by the meter 115. In one embodiment, the phase information is transmitted to the central utility controller 110 via the communication interface 204.

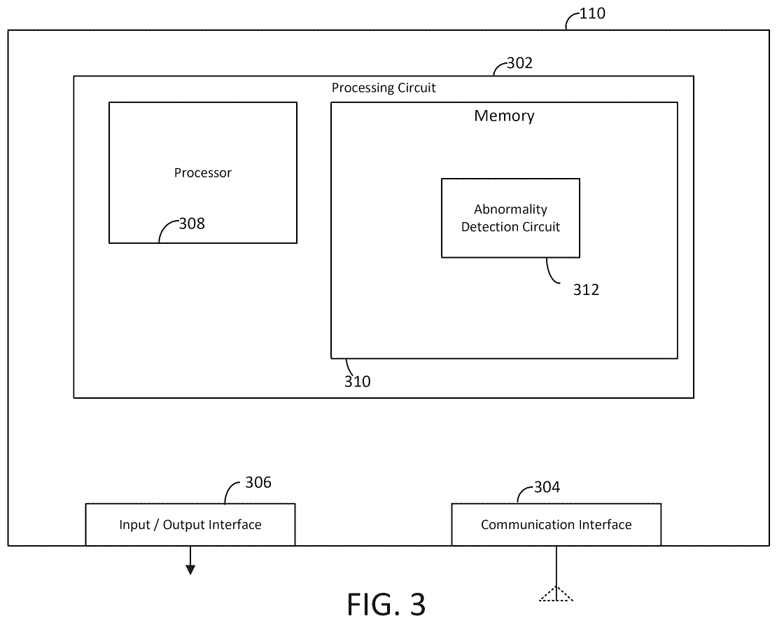

FIG. 3 illustrates a block diagram of the central utility controller 110, according to some embodiments. In some embodiments, the central utility controller 100 operates as a cloud-based software platform. As shown in FIG. 3, the central utility controller 110 includes a processing circuit 302, a communication interface 304, and an input/output (I/O) interface 306. The processing circuit 302 includes an electronic processor 308 and a memory 310. The processing circuit 302 may be communicably connected to one or more of the communication interface 304 and the I/O interface 306. The electronic processor 308 may be implemented as a programmable microprocessor, an application specific integrated circuit (ASIC), one or more field programmable gate arrays (FPGA), a group of processing components, or with other suitable electronic processing components.

The memory 310 (for example, a non-transitory, computer-readable medium) includes one or more devices (for example, RAM, ROM, flash memory, hard disk storage, etc.) for storing data and/or computer code for completing or facilitating the various processes, layers, and modules described herein. The memory 310 may include database components, object code components, script components, or other types of code and information for supporting the various activities and information structure described in the present application. According to one example, the memory 310 is communicably connected to the electronic processor 308 via the processing circuit 302 and may include computer code for executing (for example, by the processing circuit 302 and/or the electronic processor 308) one or more processes described herein.

The communication interface 304 is configured to facilitate communication between the central utility controller 110 and one or more external devices or systems, such as one or more other meters 102a-1. The communication interface 304 may be, or include, wireless communication interfaces (for example, antennas, transmitters, receivers, transceivers, etc.) for conducting data communications between the central utility controller 110 and one or more external devices, such as another meter 102a-1. In some embodiments, the communication interface 304 utilizes a proprietary protocol for communicating. For example, the proprietary protocol may be an RF-based protocol configured to provide efficient and effective communication between the central utility controller 110 and other devices. In other embodiments, other wireless communication protocols may also be used, such as cellular (3G, 4G, 5G, LTE, CDMA, etc.), Wi-Fi, LoRa, LoRaWAN, Z-wave, Thread, and/or any other applicable wireless communication protocol.

The I/O interface 306 may be configured to interface directly with one or more devices, such as a power supply, a power monitor, etc. In one embodiment, the I/O interface 214 may utilize general purpose I/O (GPIO) ports, analog inputs, digital inputs, etc.

As described above, the memory 310 may be configured to store various processes, layers, and modules, which may be executed by the electronic processor 308 and/or the processing circuit 302. In one embodiment, the memory 310 includes an abnormality detection circuit 312. The abnormality detection circuit 312 may be configured to determine, in concert with the electronic processor 308, an abnormality of one or more transformers 105 within the system 100. As detailed below, in one embodiment, the abnormality detection circuit 312 determines an abnormality based on AMI data in conjunction with an impedance model.

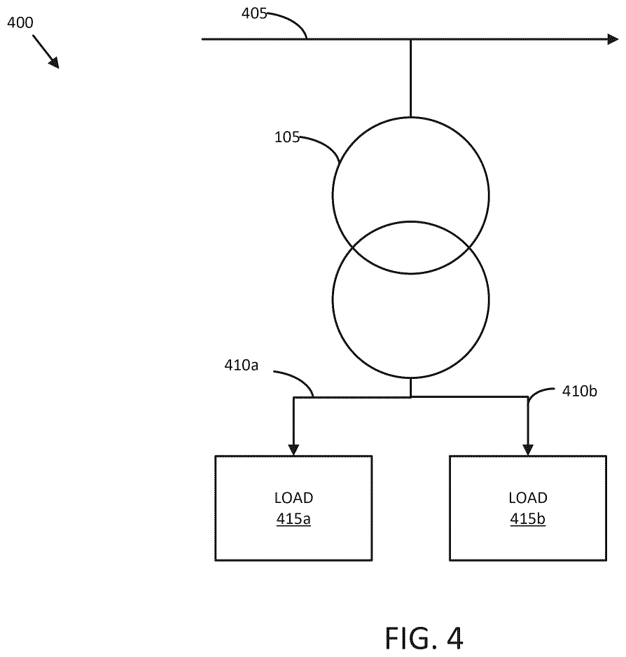

FIG. 4 illustrates a feeder segment 400 of the system 100. The segment 400 includes a lateral line 405, transformer 105, service lines 410a, 410b, and one or more loads 415a, 415b. The system 100 may include one or more feeder segments 400, one or more service lines 410 per feeder segment 400, and one or more loads 415 per service line 410. Each load 415 may be monitored by a smart meter 115. The smart meter 115 monitors and reports AMI data frames containing voltage, active and reactive power samples, and/or other auxiliary information. In some embodiments, there are multiple feeder segments 400 (for example, 400a . . . 400n) electrically connected downstream.

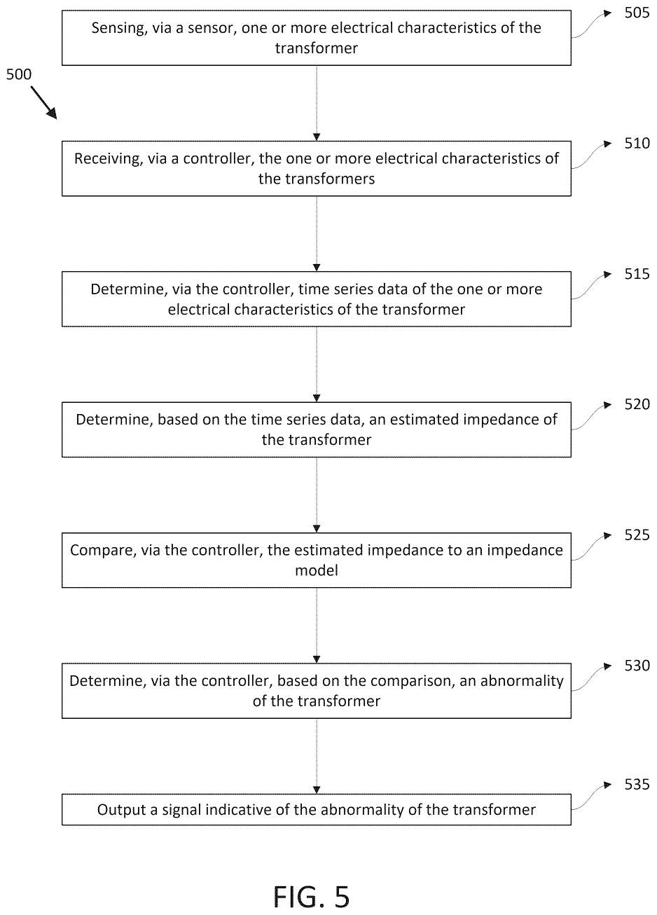

FIG. 5 is a flowchart illustrating a method 500 for determining one or more abnormalities in a transformer 105 of the system 100. The method 500 includes, at block 505, sensing, via a smart meter 115 (for example, via a sensor 216 of the smart meter 115), one or more electrical characteristics of the transformer 105. In some embodiments, the one or more electrical characteristics include AMI data discussed above.

At block 510, the controller 110 receives, the one or more electrical characteristics of the transformers 105. At block 515, the controller 110 determines time series data of the one or more electrical characteristics of the transformer. The controller 110, at block 520, then determines, based on the time series data, an estimated impedance of the transformer.

In one embodiment, the estimated impedance of the transformer is determined based on a total least squares-based method. In such an embodiment, a voltage drop across a service line 410 may be approximated by Equation 1:

$$Δ {V}_{sl , m} ( k ) \approx \vert {Z}_{sl , m} \vert {I}_{sl , m} ( k ) \qquad [ Equation 1 ]$$

Where I_{sl,m} represents the magnitude of the current flowing in the m^{th} service line of the transformer 105. Since the smart meters 115 provide samples of powers, the current magnitude may be derived by Equation 2:

$${I}_{sl , m} ( k ) = \frac{1}{{V}_{m} ( k )} \sqrt{{P}_{m}^{2} ( k ) + {Q}_{m}^{2} ( k )} \qquad [ Equation 2 ]$$

Where V₀(k) is a voltage magnitude on a secondary side of the transformer 105. In some embodiments, to estimate this voltage magnitude using AMI data, the transformer secondary voltage is related to individual loads' voltages through the following equations:

$${V}_{0} ( k ) \approx {V}_{m} ( k ) + Δ {V}_{sl , m} ( k ) \qquad [ Equation 3 ]$$

$${V}_{0} ( k ) \approx {V}_{q} ( k ) + {V}_{sl , q} ( k ) \qquad [ Equation 4 ]$$

Wherein m and q represent a pair of meters where 1 is less than or equal to m, q, which is less than or equal to M. By using Equation 3 and Equation 4, and eliminating the secondary voltages, the following equation may be derived for meters m and q:

$${V}_{m} ( k ) - {V}_{q} ( k ) \approx \vert {Z}_{sl , q} ( k ) \vert {I}_{sl , q} ( k ) - \vert {Z}_{sl , m} \vert {I}_{sl , m} ( k ) \qquad [ Equation 5 ]$$

Equation 5 illustrates that the magnitudes of line impedances may be estimated as coefficients of a linear function. Equation 2, above, indicates that the measurement noise may be present in the line current variables on the right side of Equation 5. Thus, the dependent variable and measurements may be corrupted by noise. Under such circumstances, a low-rank approximation technique may be used to obtain estimates of unknown parameters. A total least square solution may be used using Equation 6:

$$[ \frac{\vert {z}_{sl , m} \vert}{\vert {z}_{sl , q} \vert} ] \approx {( {X}_{m , q}^{T} {X}_{m , q} - {σ}^{2} I )}^{- 1} {X}_{m , q}^{T} {v}_{m , q} \qquad [ Equation 6 ]$$

Where I is the identity matrix, X_{m,q} is the ensemble matrix for the input batch of AMI data, and σ denotes the smallest singular value of the expanded matrix [X_{m,q}, V_{m,q}]. Once the impedance of service lines are estimated for the branches, the transformer secondary voltage can be estimated based on different pairs of meters. For example, using the following Equation 7:

$${V}_{0} ( k \vert m , q ) = {V}_{m} ( k ) + \frac{\vert {z}_{sl , m} \vert}{{V}_{m} ( k )} \sqrt{{P}_{m}^{2} ( k ) + {Q}_{m}^{2} ( k )} \qquad [ Equation 7 ]$$

The voltage magnitude on the secondary side of the transformer 105 may then be estimated by averaging over all pair-wise voltage estimates using Equation 8:

$${V}_{0} ( k ) = \frac{2}{M ( M - 1 )} {\sum }_{m , q} {V}_{0} ( k \vert m , q ) \qquad [ Equation 8 ]$$

In some embodiments, a linear regression-based model may then be used, following Equation 9:

$${V}_{0} ( k ) \approx {V}_{m} ( k ) + \frac{{P}_{m} ( k )}{{V}_{m} ( k )} {R}_{sl , m} + \frac{{Q}_{m} ( k )}{{V}_{m} ( k )} {X}_{sl , m} \qquad [ Equation 9 ]$$

Where Vₘ(k), Pₘ(k), and Qₘ(k) are measurements, while V₀(k), R_{sl,m}, and X_{sl,m} are unknowns. The unknown may be solved using Equation 10:

$${V}_{0}^{′} ( k ) \approx {V}_{0} ( k ) + \frac{{P}_{T} ( k )}{{V}_{0} ( k )} {R}_{tx} + \frac{{Q}_{T} ( k )}{{V}_{0} ( k )} {X}_{tx} \qquad [ Equation 10 ]$$

The impedance of the transformer 105 may then be determined using Equation 11:

$${V}_{0}^{′} ( k ) \approx {V}_{0} ( k ) + \frac{{P}_{T} ( k )}{{V}_{0} ( k )} {R}_{tx} + \frac{{Q}_{T} ( k )}{{V}_{0} ( k )} {X}_{tx} \qquad [ Equation 11 ]$$

Where V₀ illustrates the voltage magnitude on the primary side of the transformer 105, and P_{T} and Q_{T} respectively represent the total active and reactive power delivered to the loads, which can be further derived using Equations 12 and 13 below:

$${P}_{T} = {\sum }_{m = 1}^{M} {P}_{m} ( k ) \qquad [ Equation 12 ]$$

$${Q}_{T} = {\sum }_{m = 1}^{M} {Q}_{m} ( k ) \qquad [ Equation 13 ]$$

Under an assumption that the voltage magnitude on the primary side of the transformer does not change significantly over successive time indices k and k+1, the temporal voltage difference satisfies the following equation:

$${V}_{0} ( k ) - {V}_{0} ( k + 1 ) \approx ( \frac{{P}_{T} ( k + 1 )}{{V}_{0} ( k + 1 )} - \frac{{P}_{T} ( k )}{{V}_{0} ( k )} ) {R}_{tx} + ( \frac{{Q}_{T} ( k + 1 )}{{V}_{0} ( k + 1 )} - \frac{{Q}_{T} ( k )}{{V}_{0} ( k )} ) {X}_{tx} \qquad [ Equation 14 ]$$

The total least square solution for unknown resistance and resistance values in Equation 14 may be given by the following Equation 15:

$$( \begin{matrix}{R}_{tx} \\ {X}_{tx}\end{matrix} ) = {( {A}_{0}^{T} {A}_{0} - {σ}_{T}^{2} I )}^{- 1} {A}_{0}^{T} {y}_{0} \qquad [ Equation 15 ]$$

Where A₀ and y₀ are the ensemble of historical data for the targe transformer as defined below:

$${A}_{0} = [ a ( 1 ) ; … ; a ( K ) ] \qquad [ Equation 16 ]$$

$${y}_{0} = [ y ( 1 ) ; … ; y ( K ) ] \qquad [ Equation 17 ]$$

$$a ( k ) = [ \frac{{P}_{T} ( k + 1 )}{{V}_{0} ( k + 1 )} - \frac{{P}_{T} ( k )}{{V}_{0} ( k )} \frac{{Q}_{T} ( k + 1 )}{{V}_{0} ( k + 1 )} - \frac{{Q}_{T} ( k )}{{V}_{0} ( k )} \qquad [ Equation 18 ]$$

$$y ( k ) = [ {V}_{0} ( k ) - {V}_{0} ( k + 1 ) ] \qquad [ Equation 19 ]$$

Where σ₀ is the smallest singular value of the new expanded sample matrix [A₀, y₀].

In some embodiments, the controller 110 continuously receives a batch of electrical characteristic (for example, AMI) data frames and constructs a batch of data. The controller 110 may then estimate a time-series of transformer secondary voltages using Equation 8 above. The controller 110 may then obtain an approximate reactance based on Equation 15 above and the batch of data.

Returning to FIG. 5, at block 525, the controller 110 compares the estimated impedance to an impedance model. In some embodiments, block 525 includes comparing the estimated impedance to the impedance model includes comparing the estimated impedance to a predetermined impedance threshold. In some embodiments, the impedance model is based on previously sensed AMI data and/or other electrical characteristics (for example, data sensed within a time window). In some embodiments, the previously sensed AMI data and/or other electrical characteristics is fed into a multi-stage regression model to obtain estimations of the transformer impedances. The estimated impedances, along with topology/connectivity data are further processed by a classification algorithm to distinguish transformers that exhibit abnormal patterns in their estimation.

At block 530, the controller 110 determines, based on the comparison, an abnormality of the transformer 105. At block 535, the controller 110 outputs a signal indicative of the abnormality of the transformer 105.

In some embodiments, the signal output from the controller 110 may be received by an external device (for example, an external computer, laptop, smart phone, tablet, etc.). In some embodiment, the signal output from the controller 110 may initiate a shutdown procedure of the transformer 105. In other embodiments, the signal output from the controller 110 may initiate an inspection and/or a diagnostic check. In yet other embodiments, the signal output from the controller 110 may output an alert.

Embodiments provide, among other things, a method of determining one or more abnormalities in a transformer of a power distribution system. Various features and advantages of the application are set forth in the following claims.

What is claimed is:

1. A method of determining one or more abnormalities in a transformer of a power distribution system, the method comprising:
sensing, via a sensor, one or more electrical characteristics of the transformer;
receiving, via a controller, the one or more electrical characteristics of the transformers;
determining, via the controller, time series data of the one or more electrical characteristics of the transformer;
determining, based on the time series data, an estimated impedance of the transformer;
comparing, via the controller, the estimated impedance to an impedance model;
determining, via the controller, based on the comparison, an abnormality of the transformer; and
outputting a signal indicative of the abnormality of the transformer.

2. The method of claim 1, wherein the one or more electrical characteristics include at least one selected from a group consisting of a voltage magnitude, an active power delivered by the transformer, and a reactive power delivered by the transformer.

3. The method of claim 1, wherein the step of determining the estimated impedance includes:
determining a total least square problem based on the one or more electrical characteristics.

4. The method of claim 1, wherein the step of determining the estimated impedance includes:
implementing a linear regression-based method based on the one or more electrical characteristics.

5. The method of claim 1, wherein the signal initiates at least one selected from a group consisting of a shutdown procedure of the transformer, an inspection of the transformer, a diagnostic check of the transformer, and an alert to a user.

6. The method of claim 1, wherein the signal is received by an external computing device.

7. The method of claim 1, wherein the impedance model is based on previously sensed electrical characteristics of the transformer.

8. The method of claim 7, further comprising:
creating estimation of the transformer impedances using the previously sensed electrical characteristics of the transformer and a multi-stage regression model.

9. A power distribution system comprising:
a transformer;
an electrical meter connected to the transformer, the electrical meter configured to sense, via a sensor, one or more electrical characteristics of the transformers; and
a controller having an electronic processor, the controller communicatively coupled to the electrical meter, the controller configured to:
receive the one or more electrical characteristics of the transformers from the electrical meter;
determine time series data of the one or more electrical characteristics of the transformer;
determine an estimated impedance of the transformer;
compare the estimated impedance to an impedance model;
determine based on the comparison, an abnormality of the transformer; and
output a signal indicative of the abnormality of the transformer.

10. The system of claim 9, wherein the one or more electrical characteristics include at least one selected from a group consisting of a voltage magnitude, an active power delivered by the transformer, and a reactive power delivered by the transformer.

11. The system of claim 9, wherein the step of determining the estimated impedance includes:
determining a total least square problem based on the one or more electrical characteristics.

12. The system of claim 9, wherein the controller determines the estimated impedance by:
implementing a linear regression-based method based on the one or more electrical characteristics.

13. The system of claim 9, wherein the signal initiates at least one selected from a group consisting of a shutdown procedure of the transformer, an inspection of the transformer, a diagnostic check of the transformer, and an alert to a user.

14. The system of claim 9, wherein the signal is received by an external computing device.

15. The system of claim 9, wherein the impedance model is based on previously sensed electrical characteristics of the transformer.

16. The system of claim 15, further the controller is further configured to:
create estimation of the transformer impedances using the previously sensed electrical characteristics of the transformer and a multi-stage regression model.
